(19) United States
(12) Patent Application Publication
(10) Pub. No.: US 2025/0247024 A1
(43) Pub. Date: Jul. 31, 2025

(54) MAGNETIC LEVITATION SYSTEM FOR SUBSTRATE SUPPORT DEVICE

(71) Applicant: Applied Materials, Inc., Santa Clara, CA (US)

(72) Inventor: Henning Aust, Mühltal (DE)

(21) Appl. No.: 18/422,304

(22) Filed: Jan. 25, 2024

(51) Int. Cl. H02N 15/00

(52) U.S. Cl. CPC H02N 15/00

(57) ABSTRACT

A substrate support device is provided. The substrate support device includes a base secured to a processing chamber. The base includes a stator configured to generate a first magnetic field, a second magnetic field, and a third magnetic field. The substrate support device further includes a substrate support above the base for supporting a substrate. The substrate support includes a rotor with a first reactive region that interacts with the first magnetic field to control a vertical position of the substrate support, and interacts with the second magnetic field to center the substrate support to the base. The substrate support includes a second reactive region that interacts with the third magnetic field to rotate the substrate support. The first magnetic field and the first reactive region selectively levitate the substrate support to any distance within a range from 0 mm to 6 mm above a resting position.

### TECHNICAL FIELD

Embodiments of the present disclosure relate generally to a substrate support device incorporating magnetic levitation functionality, and in particular to a substrate support device incorporating magnetic levitation functionality for in-chamber processing.

### BACKGROUND

A rapid thermal processing (RTP) chamber is a specialized device used in substrate manufacturing (e.g., such as semi-conductor manufacturing). An RTP chamber's primary function is to expose substrates to rapid temperature changes for processes such as doping, oxidation, or annealing. An RTP chamber typically achieves this through the use of high-intensity heat sources such as heat lamps. These sources can quickly raise the temperature of a substrate to several hundred or even to several thousand degrees Celsius. Such rapid heating can be followed by a rapid cooling phase, making RTP a much faster alternative to traditional processing.

As mentioned, temperature control within an RTP chamber is typically achieved through a combination of heating elements, such as halogen lamps or other high-intensity heat sources, and complementary cooling mechanisms, such as forced air, or water-cooled systems.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In some aspects, a substrate support device is provided. In some aspects, the substrate support device includes a base secured to a processing chamber, the base including a stator configured to generate a first magnetic field, a second magnetic field, and a third magnetic field. In some aspects, the substrate support device further includes a substrate support positioned above the base and configured to support a substrate. In some aspects, the substrate support includes a rotor that includes a first reactive region configured to interact with the first magnetic field to magnetically control a vertical position of the substrate support, and to interact with the second magnetic field to magnetically center the substrate support to the base. In some aspects, the rotor further includes a second reactive region configured to interact with the third magnetic field to magnetically rotate the substrate support. In some aspects, the first magnetic field and first reactive portion are configured to selectively levitate the substrate support to any distance within a range from 0 mm to 6 mm above a resting position.

In some aspects, a system is provided. In some aspects, the system includes a processing chamber and a base disposed within the processing chamber and secured to a floor of the processing chamber. In some aspects, the base includes a stator configured to generate a first magnetic field, a second magnetic field, and a third magnetic field. In some aspects, the system further includes a substrate support positioned above the base and configured to support a substrate. In some aspects, the substrate support includes a rotor that includes a first reactive region configured to interact with the first magnetic field to magnetically control a vertical position of the rotor, and to interact with the second magnetic field to magnetically center the substrate support to the base. In some aspects, the rotor further includes a second reactive region configured to interact with a third magnetic field to magnetically rotate the rotor. In some aspect, the first magnetic field and first reactive region are used to selectively levitate the substrate support to any distance within a range from 0 mm to 6 mm above a resting position.

In some aspect, a method is provided. In some aspect, the method includes generating a first magnetic field via a stator of a base of a substrate support device to cause a first magnetic interaction with a first ferrous ring of a rotor attached to a substrate support of the substrate support device. In some aspects, the first magnetic interaction controls a vertical position of the substrate support. In some aspects, the method further includes selectively levitating the substrate support to any vertical distance within a range from 0 mm to 6 mm above a resting position using the first magnetic field, and generating a second magnetic field via the stator to cause a second magnetic interaction with the first ferrous ring of the rotor. In some aspects, the second magnetic interaction centers the substrate support to the base. In some aspects, the method further includes centering the substrate support with respect to the base via the second magnetic interaction over the vertical range, and generating a third magnetic field via the stator to cause a third magnetic interaction with a second ferrous ring of the rotor attached to the substrate support. In some aspects, the third magnetic interaction rotates the substrate support, and rotating the support device via the third magnetic an interaction over the vertical distance. Generating a first magnetic field via a stator of a support device configured to support a substrate within a processing chamber, displacing a rotor of the support device in a first direction via an interaction of a first reactive portion of the rotor with the generated first magnetic field, generating a second magnetic field via the stator, centering the rotor with respect to the support device via an interaction of a second reactive portion of the rotor with the generated second magnetic field, generating a third magnetic field via the stator, and displacing a rotor of the support device in a rotational direction via an interaction of a third reactive portion of the rotor with the generated third magnetic field.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1 illustrates a cross-sectional side view of a processing chamber, according to some embodiments of the present disclosure.

FIG. 2A illustrates a cut-away view of an example substrate support device of FIG. 1, according to some embodiments of the present disclosure.

FIG. 2B illustrates a top-down view of the example substrate support device of FIG. 1, according to some embodiments of the present disclosure.

FIG. 3 illustrates a cut-away view of a portion of an example substrate support device of FIG. 1, according to some embodiments of the present disclosure.

FIG. 4 illustrates a cut-away view of a portion of an example substrate support device of FIG. 1, according to some embodiments of the present disclosure.

FIG. 5A illustrates a cut-away view of an example axial levitation mechanism of the example substrate support device of FIG. 1, according to some embodiments of the present disclosure.

FIG. 5B illustrates a cut-away view of an example axial levitation mechanism of the example substrate support device of FIG. 1, according to some embodiments of the present disclosure.

FIG. 6A illustrates a partial view of an example radial positioning mechanism of the example substrate support device of FIG. 1, according to some embodiments of the present disclosure.

FIG. 6B illustrates a partial view of an example radial positioning sensing mechanism of the substrate support device of FIG. 1, according to some embodiments of the present disclosure.

FIG. 7 is a flow diagram of an example method of operating the substrate support device of FIG. 1, in accordance with one embodiment of the present disclosure.

### DETAILED DESCRIPTION

The position of the substrate within an RTP chamber relative to the heating and cooling elements is controlled to ensure uniform temperature distribution and consistent processing. For instance, if a substrate is not optimally positioned, it can lead to uneven heating or cooling of the substrate. This can result in non-uniform material properties across the substrate. For instance, areas that lie closer to the heat source might receive more heat and undergo different rates of chemical reactions, compared to areas placed farther away. This can lead to significant inconsistencies that can affect uniformity across the substrate, as well as process performance and yield.

One strategy for addressing inconsistencies, and increasing uniformity, is rotating a substrate within the RTP chamber as it is being processed. As a substrate rotates, it moves through different thermal zones within the chamber, ensuring that all parts of the substrate are exposed to the same thermal environment over time. Such rotation thus overcomes any intrinsic non-uniformities in the heating elements or chamber design.

Positional (and orientational) control of a substrate in an RTP chamber is typically achieved through mechanical systems. These systems often include use of robotic arms or precision mechanical stages that can move a substrate in various directions and angles.

Current methods of controlling substrate position and orientation face some challenges. As mentioned, precision is a concern; even slight inaccuracies in a mechanical positioning system can lead to significant variations in thermal treatment across the substrate. Additionally, there are limitations in the maximum movable distances and rotation angles that the mechanical systems can achieve, which can restrict the uniformity of treatment for larger substrates. Furthermore, the mechanical systems themselves can introduce contaminants or vibrations, which can affect the process quality.

Thus, the embodiments described herein address the above, and other challenges, by introducing a modified substrate support device incorporating a novel magnetic levitation mechanism and configuration incorporating enhanced vertical controllability. Magnetic levitation or “maglev” for short, uses induced magnetic fields to levitate and manipulate the substrate and/or substrate stages, without physical contact. Such a type of magnetic levitation can be employed for positioning and rotating substrates in RTP chambers. This reduced physical contact can reduce the risk of contamination and mechanical stress.

The proposed system and configuration can further provide mechanisms for enhancing the overall working vertical range of the levitated component (which may hold a substrate). This expanded working range can be enabled by specific geometries and configurations of the system components. Thus, the maglev mechanisms disclosed herein allow for enhanced precision and control over the substrate's position and orientation.

Advantages of the present disclosure and embodiments discussed herein include enhanced precision and controllability. By incorporating additional rotational and levitation sensors into the system, the design aims to achieve a higher level of accuracy in operations. These sensors can provide real-time feedback on various parameters, allowing for minute adjustments and more precise control over the processes involved.

Additionally, systems and methods described in the present disclosure include improvements in the range of vertical positioning of a rotor with respect to the processing chamber (and other components within, such as a heat source). By enhancing the achievable axial play of the rotor, the range and controllability of a vertical field of positioning of the rotor. This enhancement allows for a more versatile and precise positioning of the rotor along the vertical axis. Such an advancement enables precise, and further ranges of, positioning relative to other components of the processing chamber, such as a heat source. By enabling greater axial movement, the provided system can adjust the position of a substrate (with respect to a heat source) with higher accuracy, ensuring that it is placed at the optimal distance from the heat source. Processes such as RTP, relying on the uniformity and controllability of the substrate's exposure to heat, can thus be controlled with greater precision.

The ability to fine-tune the substrate's positioning in relation to the heat source means that the exact amount of heat required can be applied. This precision in control over heating leads to more uniform thermal processing. This level of control also allows for additional customization of heating profiles for different substrates.

Improvements provided by such a system directly impact the overall quality and efficiency of production. The added functionalities contribute to the uniformity of product yields. By ensuring that each unit produced meets the desired standards, the system effectively minimizes the occurrence of defects and inconsistencies. This enhancement in uniformity leads to an increase in the final product quality, making the end products more reliable and satisfactory. Additionally, the system's refined control and precision directly translate to faster throughput times; operations can be conducted more swiftly without sacrificing quality. The reduction in scrap and defective product cycles also means less waste and rework. This reduces material costs and contributes to more sustainable production practices.

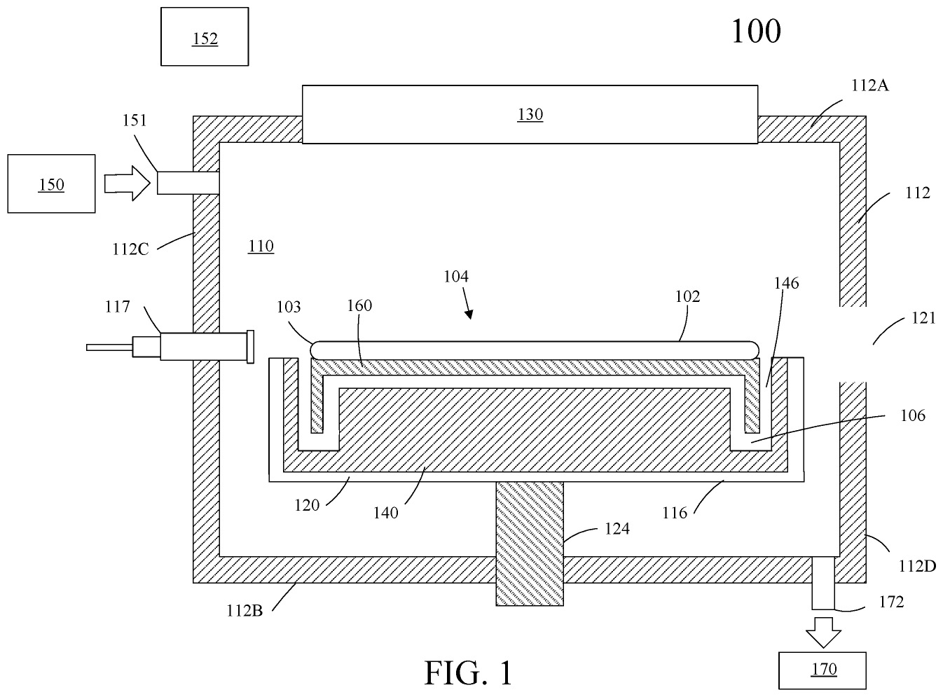

FIG. 1 illustrates a cross-sectional view of an exemplary processing chamber 100 (e.g., an RTP chamber) of a substrate manufacturing system, according to some embodiments of the present disclosure.

In embodiments, processing chamber 100 may perform thermal processes. In some embodiments, processing chamber 100 may perform plasma-based processes. Alternatively, processing chamber may perform non-plasma processes. In some cases, processing chamber 100 may be suitable for a thermal process (e.g., RTP), an etching operation, a deposition operation, a chamber cleaning operation, a plasma treatment operation, or any other type of operation typical of a semiconductor manufacturing facility. In an embodiment, one or more substrates (e.g., wafers) 102 may be provided within the processing chamber.

In some embodiments, the chamber 100 may include a thermal energy source 130, which may be a continuous energy source. In some embodiments, thermal energy source 130 may be a thermal energy source such as one or more heat lamp, one or more infrared (IR) sources (e.g., that may direct IR light onto regions of a substrate via fiber optics, one or more resistive heating elements, one or more convective heater, one or more microwave energy source, etc. In some embodiments, thermal energy source 130 may be any energy source capable of delivering thermal energy to (i.e., heating of) a substrate.

As seen, processing chamber 100 may include a chamber body 112. The chamber body 112 at least partially defines a processing volume 110. In some embodiments, the chamber body 112 includes a top wall 112A (e.g., a ceiling or lid), a bottom wall 112B (e.g., a floor) opposite the top wall 112A, a first sidewall 112C coupling the top wall 112A and the bottom wall 112B, and a second sidewall 112D opposite the first sidewall 112C. The chamber body 112 may be or include any material suitable with the processes performed in the processing chamber 100. For example, suitable materials fort the chamber body 112 include aluminum, stainless steel, ceramic materials, or a combination thereof.

At least one substrate support device 104 may be disposed in the processing volume 110 to support one or more substrate(s) 102 thereupon during processing. In some embodiments, a substrate support device 104 may include a base 116, which may be part of a substrate support pedestal (which may be or include the stator 120, housing 140, and rotor 160) attached to a shaft 124. In some embodiments, base 116 includes a cooling plate having one or more cooling channels through which coolant may flow. In some embodiments, base 116 includes one or more heating elements. Substrate support device 104 may include a substrate support 158 that may rest on and/or be positioned above base 116. Substrate support 158 may support a substrate during processing (e.g., RTP). In embodiments, substrate support 158 includes one or more chucking electrodes, one or more heating electrodes, one or more radiofrequency (RF) electrodes, and so on. In some embodiments, substrate support 158 is powered. In some embodiments, substrate support is not powered (and optionally may not include any electrodes).

In embodiments, the substrate(s) 102 can be brought into the processing volume 110 through a loading port 121. The substrate(s) 102 can include a surface 103 on which devices and/or processing takes place. The substrate support 158 and/or base 116 may include such components as an electrostatic chuck, clamps, edge rings, guide pins, or the like for physically locating and retaining the substrate.

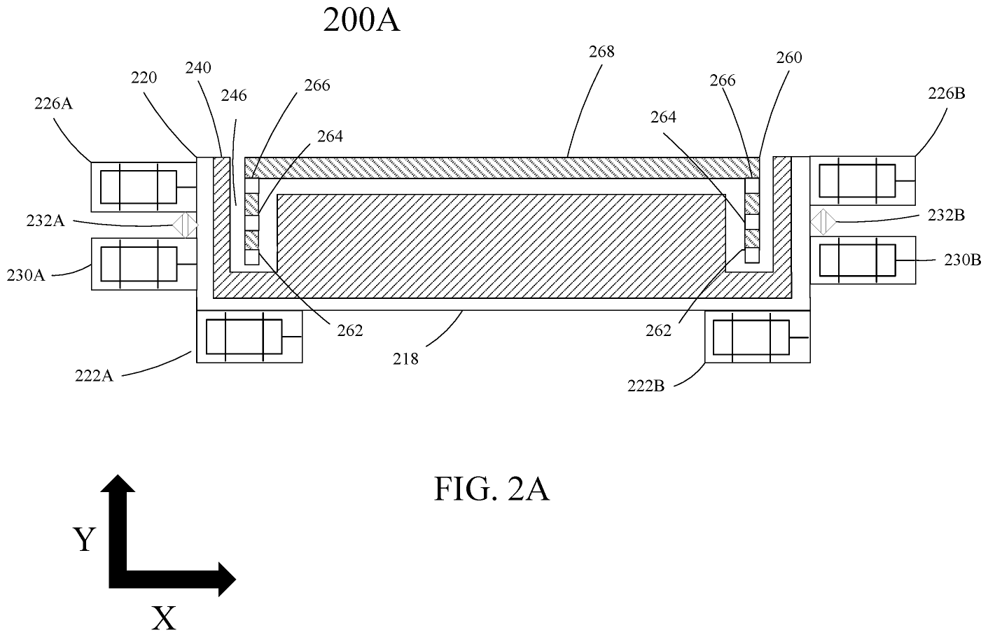

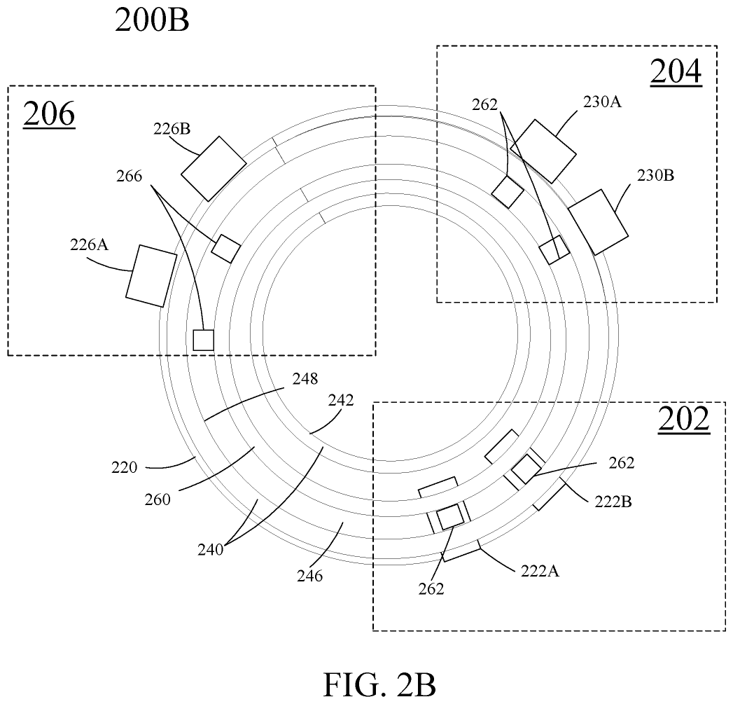

In some embodiments, the substrate support device 104 may be configured for rotating a substrate 102 during processing. In some embodiments, the substrate support device 104 may include a maglev mechanism for supporting and rotating the substrate 102 during processing. Such a mechanism will be described in detail below and with respect to FIGS. 2A-6B.

In some embodiments, the chamber 100 may further includes one or more substrate temperature sensor 117. The substrate temperature sensor 117 may be embedded in the chamber body 112, substrate support pedestal (which may be or include the stator 120, housing 140, and rotor 160), and/or in any other suitable location. In some embodiments, the substrate temperature sensor 117 may measure the temperature of substrate(s) 102 and sends the temperature measurement to a hub/data processing unit (not pictured) and/or to a controller 152. In some embodiments, substrate temperature sensor 117 may be a pyrometer. In some embodiments, the substrate temperature sensor may be any suitable temperature sensor. For example, the substrate temperature sensor 117 may be at least one of a thermocouple, resistance temperature detector, thermistor, infrared temperature sensor, semiconductor temperature sensor, fiber optic temperature sensor, etc. In embodiments, multiple substrate temperature sensors 117 may be used, which may be positioned within substrate support 158, within base 116, within walls, a top and/or a bottom of processing chamber 100, and so on.

During a manufacturing process (e.g., RTP), conditions in processing chamber 100 may be monitored by sensors (e.g., temperature sensor 117). Data indicative of measurements made by the sensor may be provided to system controller 152.

The processing system 100 may further include the thermal energy source 130. In some embodiments, the thermal energy source 130 may be, but is not limited to, a microwave energy source, an optical radiation source (e.g., laser or flash lamp), an electron beam source, a resistive heating source, and/or an ion beam source. The thermal energy source 130 can provide heating in a continuous or pulsed manner. In embodiments, the thermal energy source 130 may be a microwave energy source. The thermal energy source 130 may be coupled with the chamber body 112 via a waveguide in some embodiments.

Thermal energy generated by the thermal energy source 130 may be supplied into the processing volume 110 from a top-most position within the chamber 100 (e.g., from the top wall 112A). Although FIG. 1 shows the thermal energy source disposed along the top wall 112A of the chamber body 112, the thermal energy source may also be placed in other locations such as the bottom wall 112B, the first sidewall 112C, the second sidewall 112D, or a combination of different locations. In embodiments, more than one thermal energy source at more than one location may be used, as is feasible.

In some embodiments, the thermal energy source 130 is positioned to heat the entire substrate(s) 102. The thermal energy source 130 may be positioned to deliver emitted thermal energy 190 perpendicular to the major surface 103 of the substrate(s) 102 positioned on the substrate support pedestal (which may be or include the stator 120, housing 140, and rotor 160) and/or at different angles. The thermal energy source 130 may be a continuous or pulsed source. In particular embodiments, the thermal energy source 130 is a continuous source. In particular embodiments, the thermal energy source 130 is a microwave energy source (e.g., a continuous microwave energy source).

In some embodiments, the thermal energy source 130 is a microwave generator. The microwave generator may generate a fixed frequency microwave or a variable frequency microwave.

In some embodiments, the processing system 100 further includes a gas supply 150. Gas supply 150 may be fluidly coupled with the processing volume via a gas inlet port 151. Gas supply 150 may be coupled to the processing chamber body 112 at any suitable location for supplying gas to the processing volume 110, such as along first sidewall 112C of the chamber body 112, as illustrated. For example, depending upon chamber design and process gas flow considerations, gas inlet port 151 may be located at any suitable location in the processing chamber 100, such as in the first sidewall 112C, second sidewall 112D of the processing chamber 100, above or below the surface of the substrate support pedestal (which may be or include the stator 120, housing 140, and rotor 160), in the top wall 112A of the processing chamber 100, in the bottom wall 112B of the processing chamber 100, or in any other suitable location. In some embodiments, gas supply 150 may include one or more pumps and valves utilized to regulate the pressure of processing volume 110 of processing chamber 100. In embodiments, a gas supply may provide one or more gases into the processing volume 110 during processing. In some embodiments, the gas(es) may be or include at least one of helium, nitrogen, oxygen, argon, carbon dioxide, carbon monoxide, ammonia, hydrogen sulfide, fluorine, chlorine, or a combination thereof. Examples of processing gases that may be used to process substrates in processing chamber 100 include halogen-containing gases, such as C₂F₆, SF₆, SiCl₄, HBr, NF₃, CF₄, CHF₃, F₂, Cl₂, CCl₄, BCl₃, and SiF₄, among others, and other gases such as O₂ or N₂O. Examples of carrier gases include N₂, He, AR, and other gases inert to process gases (e.g., non-reactive gases).

In some embodiments, the gas supply 150 may provide one or more suitable process gases for processing the substrate(s) 102 and/or for maintaining the processing volume 110 (such as annealing gases, deposition gases, etch gases, cleaning gases, or the like). For example, embodiments of the present disclosure may be used in annealing, deposition, or implant processes that use certain gases be provided to the processing volume 110. The gases may be reactive, such as precursors for deposition processes, or nonreactive, such as inert gases commonly used in conventional thermal processes.

Other components for controlling the flow of gases to the processing volume 110, such as flow controllers, valves, or the like, are, for simplicity, not shown.

In some embodiments, substrate support 158 may leave a portion of a surface area (e.g., surface 103) of the substrate(s) 102 exposed to processing volume 110, and a gas and/or plasma is circulated within the processing volume 110 during processing.

In some embodiments, the processing system 100 further includes exhaust system 170. In one implementation, the exhaust system 170 is coupled to the processing chamber body 112 via an exhaust port 172. The exhaust system 170 may be coupled to the processing chamber body 112 at any suitable location for exhausting the processing volume 110, such as along the bottom wall 112B of the chamber body 112, as illustrated. For example, depending upon chamber design and process gas flow considerations, the exhaust port 172 may be located at any suitable location in the processing chamber 100, such as in the first sidewall 112C, second sidewall 112D of the processing chamber 100, above or below the surface of the substrate support pedestal (which may be or include the stator 120, housing 140, and rotor 160), in the top wall 112A of the processing chamber 100, in the bottom wall 112B of the processing chamber 100, or in any other suitable location. In some embodiments, exhaust system 170 may include one or more pumps and valves utilized to evacuate and regulate the pressure of processing volume 110 of processing chamber 100.

In some embodiments, exhaust system 170 may include or be a pump system that may include one or more pumps, valves, lines, manifolds, tanks, etc., utilized to evacuate and regulate the pressure of interior volume 110. One or more other pressure sensors and/or flow sensors may be disposed within the processing chamber, at the exhaust port, and/or at other locations.

In some embodiments, processing chamber 100 may be a batch processing chamber that has substrate support assemblies for supporting multiple substrates. In one embodiment, processing chamber 100 may include a single chamber and/or a single substrate support assembly (e.g., a single substrate support device 104).

In some embodiments, each chamber may accommodate one or more substrates that are supported by one or more substrate support devices 104. The substrate support device 104 of a RTP chamber typically refers to the structure or device that holds the substrate in place. Each substrate support device 104 may be designed to securely hold the substrate during processing while ensuring that it can be moved into and out of the RTP chamber with ease and without damage. In some embodiments, substrate support devices may be or include flat platforms or trays on which the substrate 102 rests. These may be static or include mechanisms for rotation or other movement, such as vertical movement. In some embodiments, substrate support devices 104 may also include clamping (e.g., electrodes for electrostatic clamping) or other securement mechanisms to keep the substrate in place, particularly during any movements.

In some embodiments, one or more portions of substrate support devices 104 may be configured to move within their respective processing chamber 100. For example, in some embodiments, substrate support device 104 may each be attached to an indexer (not shown in FIG. 1), configured to raise, or lower or otherwise move the substrate support device 104 with respect to the processing chamber 100 (independent of a maglev mechanism as described below). In some embodiments, the substrate support device(s) 104 may be laterally displaced, so as to securely receive a substrate. For example, in some embodiments, the lateral position of a substrate support device 104 may be calibrated to properly interact with an end effector of the system. Thus, in some embodiments, the position of the substrate support device 104 may be adjusted in any dimension with respect to the processing chamber 100.

As mentioned, in some embodiments, the substrate support device 104 may include a maglev mechanism that may include base 116 including a stator 120 and a substrate support 158 including a rotor 160 (which will be further described within FIGS. 2A-6B below). In some embodiments the stator 120 may include one or more motors (as will be described with respect to FIGS. 2A-6B), or electrical coils, to generate one or more magnetic fields to engage and/or control the levitation, stability, and/or rotation of the rotor 160 (and of the substrate support 158 and its supported substrate 102). The stator 120 and/or base 116 may further include one or more sensors for providing feedback on the levitation, stability, and rotation of the rotor.

In embodiments, the base 116 may include a housing 140, which may serve as a structural component of the magnetic levitation system. In embodiments, the housing may isolate the partially internal rotor 160, from the external stator. In embodiments, the housing may be constructed from materials selected for strength and transfer of magnetic properties. The housing may be designed to shield components of the system from external magnetic interference and/or environmental factors. In some embodiments, the housing may include the stator, or stator functionalities.

The rotor 160 may include magnetic materials, or regions, that interact with the magnetic field (e.g., such a ferromagnetic, diamagnetic, paramagnetic materials or regions, etc.), generated by the stator 120.

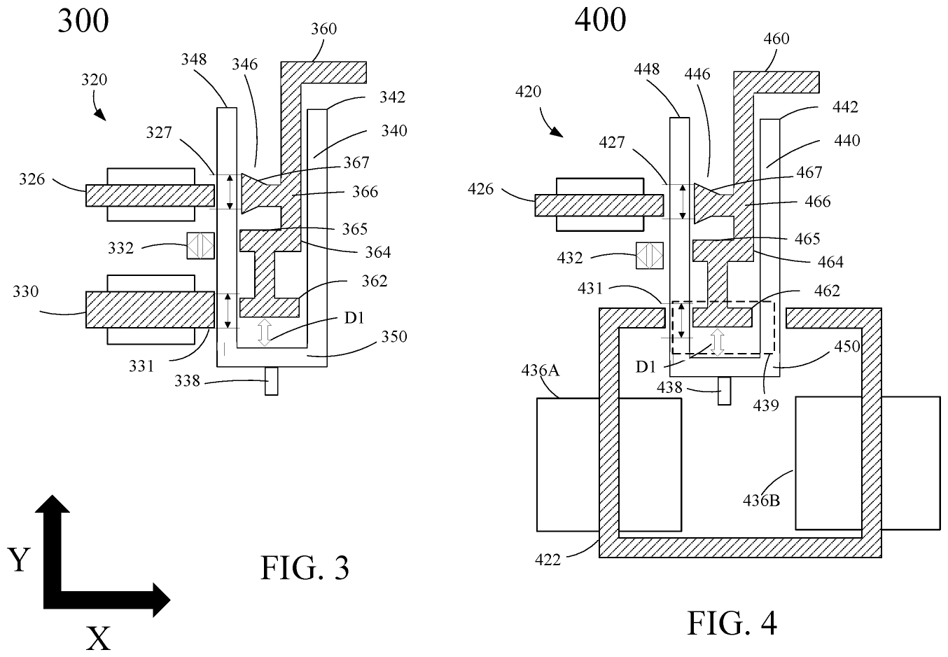

In some embodiments, the stator may generate the magnetic fields via motors (not shown in FIG. 1). In some cases, these may be switched reluctance motors (SR motors, or SRMs). In some cases these may be any other type of motor capable of generating a magnetic field, including permanent magnet motors and inductive motors (as will be further described with respect to FIG. 3C). Such an interaction may enable the rotor to levitate and/or rotate with minimal friction.

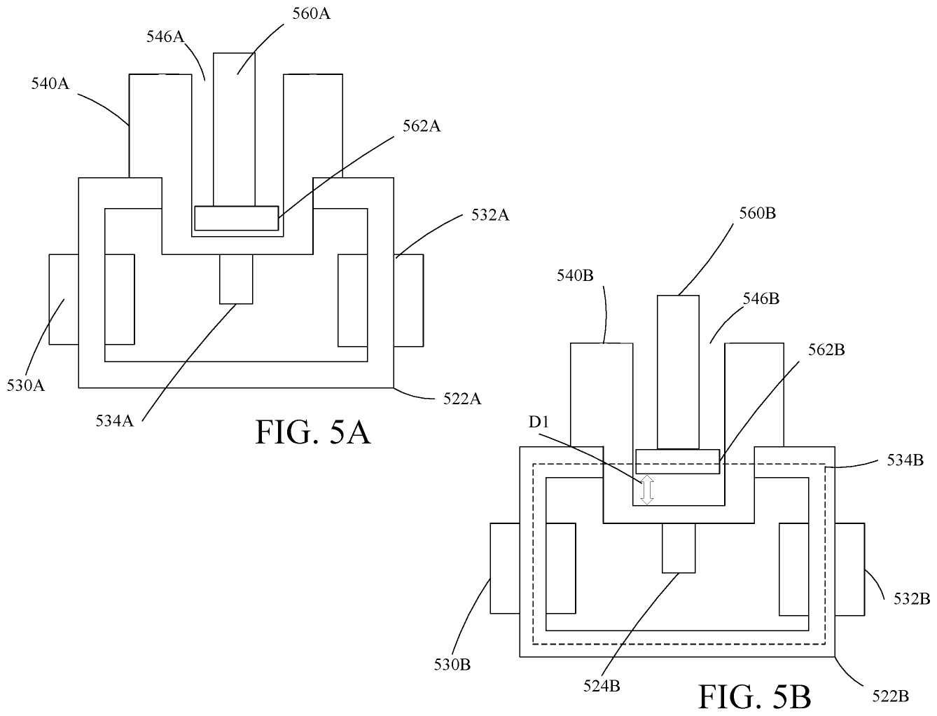

In some embodiments, the maglev system (e.g., the stator 120) may raise and lower the rotor 160 (and substrate support 158 and supported substrate 102) during processing. For instance, in some embodiments, the stator 120 may be energized to raise and lower the rotor 160 (as well as the substrate support 158 and substrate 102) by a vertical distance 106 (as will be further described with respect to FIGS. 5A-B). In embodiments, the maglev system and stator 120 may raise the rotor 160 by generating a controlled magnetic field.

In some embodiments, the rotor 160 may rest within a well 146, or a gap, within the housing 140 and/or base 116. In some embodiments, once raised, the rotor 160 (and substrate support 158 and substrate 102) may levitate, and a portion of the rotor 160 may remain within the well 146. While the substrate support 158 levitates a distance above the base 116, the stator 120 may induce, or cause, the rotor 160 (and thus the substrate support 158) to rotate, thus rotating supported substrate 102. In embodiments, the rotor 160 may rotate while the stator 120 and base 116 remain stationary. In some embodiments, both rotation and vertical displacement of the rotor 160 and substrate support 158 may be precisely measured and controlled (as will be further described with respect to FIGS. 3A-6B). In some embodiments, when the maglev system is unenergized, the substrate support 158 may rest at resting position by physically contacting the housing.

The processing chamber and/or thermal energy source may be connected to a controller 152, which may control processing parameters of the thermal energy source, the processing chamber, etc. (e.g., by controlling set points, loading recipes, and so on). One or more flow sensors and/or pressure sensors may be connected to the gas line(s) (e.g., at port 151, port 172) to detect gas flow characteristics, in some embodiments. The controller 152 may receive data from the one or more flow sensors and/or pressure sensors, as well as temperature sensors and/or other sensors within the processing chamber 100 in embodiments. Based on the measurements (e.g., temperature measurements of one or more regions of substrate support device 104 and/or of substrate 102, controller 152 may adjust one or more processing parameters, such as a distance between substrate 102 and thermal energy source 130, a rate of rotation of substrate 102, temperature setpoints of thermal energy source 130 and/or cooling lines within base 116, and so on.

System controller 152 may control one or more parameters and/or set points of processing chamber 100 and/or support device 104. Such a controller 152 can be and/or include a computing device such as a personal computer, a server computer, a programmable logic controller (PLC), a microcontroller, and so on. Such a controller may include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. Such a controller can include a data storage device (e.g., one or more disk drives and/or solid-state drives), a main memory, a static memory, a network interface, and/or other components.

Such a controller can execute instructions to perform any one or more of the methodologies and/or embodiments described herein. The instructions can be stored on a computer readable storage medium, which can include the main memory, static memory, secondary storage and/or processing device (during execution of the instructions).

In embodiments, such a controller may receive measurements from one or more flow sensors and/or pressure sensors indicating a flow parameter and/or pressure parameter (e.g., pressure, flow rate, etc.). Such a controller may adjust one or more properties or settings (e.g., such as a plasma power, temperature, plasma frequency, pump rate, gas flow rate for one or more gases, etc.) of processing chamber 100. Such as controller can also be configured to permit entry and display of data, operating commands, and the like by a human operator.

In some embodiments, the controller 152 may engage and adjust any of the operations associated with the substrate support device 104. Such operations may include levitation, rotation, and positional adjustment in any direction (vertical, horizontal, rotational, etc.). In some embodiments, controller 152 may receive sensor measurements from sensors associated with the substrate support device 104 and/or associated with substrate 102 and/or any sensors associated with the maglev mechanism (e.g., rotational positional sensors, or encoder mechanisms and sensors). In embodiments, the controller 152 may use this data to adjust or alter the outputs that control the maglev mechanisms. In embodiments, this may form a closed loop or feedback loop. For example, controller 152 may determine a temperature of one or more regions of substrate 104, a temperature of base 116 and/or a temperature of thermal source 130, and may adjust a height and/or rotational speed of substrate support 158 based on such data.

FIG. 2A illustrates a cut-away side view of an example substrate support device of FIG. 1, according to some embodiments of the present disclosure.

Components and features as seen and described in FIG. 2A may correspond, or be similar, to similar components as seen and described with respect to FIG. 1. Thus, embodiments discussed with respect to FIG. 2A may incorporate and augment at least the embodiments described with respect to FIG. 1.

In embodiments, a substrate support device 200A includes a base 118 secured to a processing chamber and a substrate support 268 disposed on the base 118. The base 118 may include a stator 220, and substrate support 268 may include a rotor 260 of the substrate support device 200A. The base 118 and substrate support 268 may be arranged concentrically, as seen in FIG. 2A-B. As discussed with respect to FIG. 1, in some embodiments, at least a portion of the base 218 and/or the stator 220 may reside outside of a chamber housing 240 (e.g., outside of a wall of the chamber, and optionally in an atmospheric environment), while the substrate support 268 may be disposed within the interior volume of the processing chamber. In embodiments, portions of the rotor 260 may reside within a well portion of the base 218 and/or housing 240.

In embodiments, the stator 220 may include various types of actuating components for generating a magnetic field and exerting a force onto the rotor 260. In embodiments, the stator 220 may include three types of actuating components, axial lift components (e.g., components 222A-B), radial movement components (e.g., components 226A-B), and centering components (e.g., components 230A-B). In embodiments, axial lift components 222A-B may provide a vertical force to lift or levitate the rotor 260 and substrate support 268. In embodiments, radial movement components 226A-B may provide a radial force to cause the rotor 260 and substrate support 268 to rotate, once levitated. In embodiments, centering components 230A-B may provide a radially inward or outward radial force to cause the rotor 260 and substrate support 268 to center with respect to the base 218. In embodiments, the rotor 260 may also be centered to fit evenly within a well (e.g., well 246) of the housing.

In embodiments, the actuating components of the stator 220 may exert a magnetic force, or movement force, on corresponding reactive regions, or portions, of the rotor 260. For instance, the rotor 260 may include various types of reactive regions that react to the generated magnetic fields of the components and thus cause the rotor to levitate, translate, rotate, center, or otherwise move. In embodiments, such regions of the rotor may be designed, or be crafted, with specific materials (e.g., ferrous materials such as iron) for engaging with the magnetic fields as generated by the actuating components.

In embodiments, the rotor 260 may include two types of reactive regions, an actuator ring 262, and a motor ring (e.g., motor ring 266). Such reactive regions of the rotor may respond, or react, to the magnetic fields generated by the actuator components. In embodiments, the actuator ring 262 may be disposed on, or be a portion of, a lower, annular and/or lower-most portion of the rotor 260. In embodiments, the motor ring 266 may be similarly annular and be disposed on, or be a portion of, an upper and/or annular portion of the rotor 260.

In embodiments, actuator ring 262 may react to the magnetic fields exerted by both axial lift components (e.g., components 222A-B) and centering components (e.g., components 230A-B). In embodiments, a single ring (actuator ring 262) is used for both axial lift (e.g., vertical movement) and centering of the substrate support 268. In embodiments, the actuator ring 262 may respond to the magnetic fields created by axial lift components 222A-B and may thus be used to provide a vertical force to lift or levitate the rotor. In embodiments, actuator ring 262 and axial lift components 222A-B are configured such that the substrate support 268 has a range of vertical motion of 3 mm, 4 mm, 5 mm, 6 mm, 7 mm, 8 mm or greater. In embodiments, the actuator ring may also respond to the magnetic fields created by the centering components 230A-B over the vertical range of motion of the substrate support 268 and may thus be used to provide a radially inward or outward radial force to cause the rotor 260 to center with respect to the base 218 over the full range of vertical motion. In embodiments, the actuator ring may also be centered to fit evenly within a well (e.g., well 246) of the housing.

In embodiments, motor ring 266 may react to the magnetic fields exerted by radial movement components 226A-B. In embodiments, the motor ring 266 may respond to the magnetic fields created by radial movement components 226A-B and may thus be used to provide a radial force to cause the rotor to rotate (e.g., once levitated). In particular, motor ring 266 may include discrete protrusions, or points, which engage or interact with the created magnetic fields. In embodiments, motor ring 266 includes gears or teeth that enable the substrate support to be rotated by adjusting the magnetic field of the radial movement components 226A-B.

Through such corresponding pairs (or trios, or more groupings) of the stator 220 and rotor 260, the stator 220 may cause the rotor 260 to levitate, translate, rotate, center, or otherwise move. In embodiments, to perform such actions, the axial lift components 222A-B may be placed at or about vertically in line (e.g., in line in the Y direction) with the actuator ring 262. Similarly, the centering components 230A-B may be placed at or about at the same height (e.g., in line in the X direction) with the actuator ring. In some embodiments, the rotational movement components 226A-B may be placed at the same height (e.g., in line in the X direction) with the motor ring 266.

In some embodiments, the axial lift components (e.g., components 222A-B) may be in a position that is beneath the base 218 and/or on a side of the base 218. In embodiments, the axial lift components 22A-B may be beneath the well of the base 218, and beneath the rotor 260. In embodiments, the rotational movement components (e.g., components 226A-B) may be placed at an uppermost position with respect to other actuating components of the stator 220. In embodiments, the centering components (e.g., components 230A-B) may be placed at a height between the axial lift components 222A-B and the rotational movement components 226A-B.

In embodiments, the stator 220, rotor 260, base 218 and/or substrate support 268 may be of a body shape that is circular. In embodiments, such a circular stator 220 may include any number of such actuating components placed around the exterior of the base 218. For instance, any number, or type of the mentioned actuating components may be placed along the periphery, or outer diameter of the base. In some embodiments, any number and/or type of the mentioned actuating components may be placed along an exterior surface or bottom of the base. In embodiments, such components may be placed at any height, or distance, or placement along the outer circumference or bottom. For instance, in embodiments, the stator may include any number of actuating components (e.g., 3, or 4, or 5, etc.) evenly, or non-evenly, placed around an outer diameter of the stator.

Similar to components 226A-B and 230A-B, the stator may include rotational sensors 232A-B. In embodiments, the rotational sensors may correspond to, and interact with, an encoder ring 264 of the rotor.

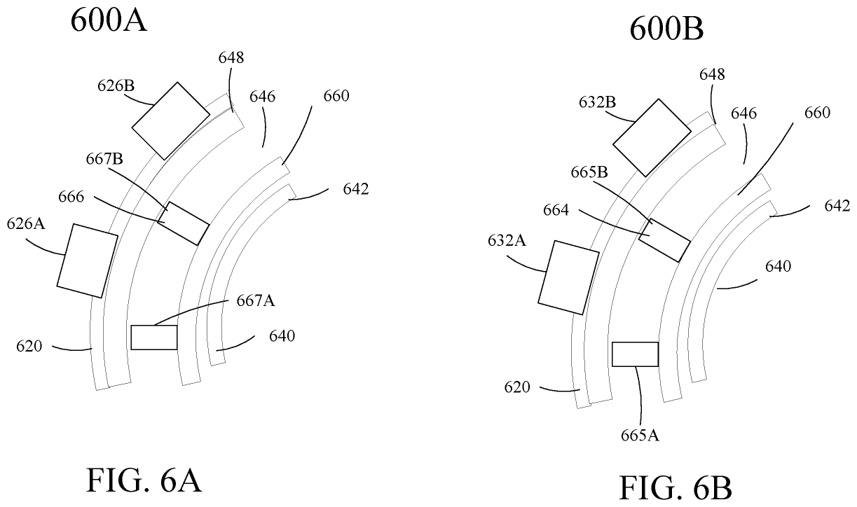

In embodiments, the encoder ring may be placed between the motor ring and the actuator ring (e.g., with respect to the Y axis). Rotational sensors 232A-B may be magnetic sensors, and may detect the encoder ring. Based on detections of the encoder ring by the rotational sensors 232A-B, controller 152 may determine a rotational position of the substrate support 268, a speed of rotation of the substrate support 268, and so on. In embodiments, the encoder ring may be disposed on, or be a portion of, a middle or meso portion of the rotor. In embodiments, the encoder ring may include a series of protruding points (as is known with respect to encoder rings) which the rotational sensors may sense, or interact with, to generate data indicative of the real-time, rotational position of the rotor. Such data may be used to generate a closed feedback loop, and monitor the real-time, rotational position of the rotor (such components will be further described with respect to FIGS. 6A-B).

In embodiments, the stator may also include or incorporate an axial sensor(s) (not shown in FIG. 2A, and will be further described with respect to FIGS. 5A-B) for sensing the axial position of the rotor. In embodiments, the axial sensors may interact, or engage, with the actuator ring, and may sense a distance to the actuator ring and rotor. In embodiments, the axial sensors may sense a distance associated with, or indicative of, the level of levitation of the rotor. Thus, the axial sensors may generate data indicative of the real-time, vertical displacement (e.g., levitation) of the rotor. Axial sensors -B may be magnetic sensors, and may detect the encoder ring and/or other regions or components of substrate support 268 and/or rotor 260. Based on detections of the rotor 260 by the axial sensors -B, controller 152 may determine a vertical position of the substrate support 268. Such data may be used to generate a closed feedback loop, and monitor the real-time, vertical displacement of the rotor.

FIG. 2B illustrates a top-down view of the example substrate support device of FIG. 1, according to some embodiments of the present disclosure.

Components and features as seen and described in FIG. 2B may correspond, or be similar, to similarly named components as seen and described with respect to FIGS. 1-2A. Thus, embodiments discussed with respect to FIG. 2B may incorporate and augment at least the embodiments described with respect to FIGS. 1-2A.

In embodiments, FIG. 2B can include working regions 202, 204, and 206 of a substrate support device 200B. In embodiments, regions 202, 204, and 206 may correspond to the working regions of actuating and reactive components (as described with respect to FIG. 2A) and of the support device 200A or 200B. For instance, in embodiments, axial lift region 202 may include axial lift components 222A-B and an actuator ring 262 of the device that cause the rotor to lift (as will be further discussed with respect to FIG. 5A-B). Radial centering region 204 of the device may include centering components 230A-B and actuator ring 262 of the device that cause the rotor to center radially, e.g., with respect to the base, well 246, stator, and overall device. Radial actuating region 206 may include radial movement components 226A-B and motor ring 266 of the device that cause the rotor of the substrate support to rotate as will be further discussed with respect to FIG. 6A-B). In embodiments, such components may function and perform as described with respect to FIG. 2A (and incorporate and augment at least the embodiments discussed therein.

Although each region e.g., regions 202, 204 and 206 of the device 200B are seen along a single plane in FIG. 2B, such a design is simplified and exemplary top-down view. As was seen in FIG. 2A, in application, such regions and their corresponding components may be placed at any height with respect to each other and respect to the stator, rotor, and housing of the substrate support device. Furthermore, although each region is shown with a limited number of components, placed at a side, or portion, of the circumference of the device, such a view is simplified and exemplary view. In application, such regions and components may include any number of components. Such regions may expand or traverse the entire circumference of the rotor, stator, housing, and device in general. In embodiments, each region 202, 204, and 206 as seen and described with respect to FIG. 2B may include as many components as necessary.

In some embodiments, the portions of the motor ring 266 and actuator ring 262 visible within FIG. 2B may correspond or be protruding portions or discrete points, of such components. For instance, rotor 260 may be of any circumference and diameter as to support a substrate of substrate manufacturing system 100 (as seen with respect to FIG. 1). In some embodiments rotor 260 may have an inner diameter ranging from 10 inches to 14 inches. In some embodiments, rotor 260 may have an outer diameter ranging from 12 to 16 inches. In embodiments, the portion, or points, visible as motor ring 266 may actually be points (e.g., teeth or gears) of the motor ring of the rotor that extend past the inner diameter and/or the outer diameter of the rotor 260. Thus, as seen, rotor 260 may include any number of discrete points as necessary to aid in driving, controlling, and/or maintaining the stability of the rotation of the rotor. Such a configuration will be further described with respect to FIG. 3.

Although not visible in the top-down view seen in FIG. 2B, rotor 260 may also include encoder rings and/or actuator rings that similarly include points that radially extend from an inner circumference of the rotor. Particularly with reference to the encoder ring, which may include distinct and protruding points as was discussed with respect to the rotor. Such elements will be visible, and further described with respect to FIG. 3. In embodiments, any of the reactive regions or portions may include any number of protruding points (e.g., teeth, gears, etc.), as necessary to aid and enhance in the responding to a force of an actuating component.

In embodiments, the device 200B may include axial and rotational sensors (not shown in FIG. 2B), as were described with respect to FIG. 2A.

As seen in FIG. 2B and as was discussed with respect to FIG. 2A, components of the rotor, stator, base, and substrate support may be concentrically placed or configured. For instance, the housing 240 may include an inner wall 242 and an outer wall 244. A portion of the rotor 260 (as described with respect to FIG. 2A) may rest between these walls of the base in well 246. Rotor may be made to levitate (e.g. in the direction in and out of the page), and rotate (e.g., clockwise, or counterclockwise), with respect to the stator and the base, which may be stationary.

In embodiments, the rotor 260 may be part of the substrate support and reside within an interior of a processing chamber, while the stator 220 may reside outside of the processing chamber interior. In embodiments, the stator 220 and components of may be incorporated into the base, processing chamber wall and/or a housing. In embodiments, the stator 220 may exert a magnetic field or force on rotor 260, that is transmitted through the chamber wall, housing, and/or a wall of the base. In embodiments, such a magnetic force may control translation of the rotor, as well as rotation of the rotor. In embodiments, the movement of the rotor may correlate with the movement of a substrate supported by the rotor.

In embodiments, the base may define an interior space, or portion of the chamber, which is held at a different pressure than that exterior the interior space. For instance, the interior of the base, which may hold the rotor, may be kept at vacuum, or near vacuum pressure, while the exterior of the chamber may be unregulated, or at atmospheric temperature.

FIG. 3 illustrates a cut-away view of a portion of an example substrate support device of FIG. 1, according to some embodiments of the present disclosure.

Components and features as seen and described with respect to FIG. 3 may correspond, or be similar, to similar components as seen and described with respect to FIGS. 1-2B. Thus, embodiments discussed with respect to FIG. 3 may incorporate and augment at least the embodiments described with respect to FIGS. 1-2B. As seen in FIG. 3, in embodiments, a substrate support device 300 may include a stator 320, a housing 340 (e.g., a portion of a base), and a rotor 360 (which may be part of a substrate support). Such components may correspond to the stator, base, and rotor (and substrate support) as seen with respect to FIGS. 1-2B. Such components may incorporate and augment at least the embodiments described therein.

As previously discussed, stator 320 may include actuating portions and sensing portions. Stator 320 may include axial lift components (which will be shown and discussed with respect to FIG. 4), radial movement components (e.g., component 326), and centering components (e.g., component 330). Stator 320 may further include axial sensors (e.g., sensor 338) and rotational sensors (e.g., sensor 332).

Stator 320 may generate various forces and magnetic fields for interacting with the rotor 360. As previously discussed, rotor 360 may rest within the well 346 of the housing 340 (e.g., between an outer wall 348 and an inner wall 342). Rotor 360 may be circular in shape, and include reactive regions, such as actuator ring 362 and motor ring 366. As seen in FIG. 3, the motor ring may include radially protruding or distinct portions or points (e.g., point 367 such as a tooth or gear). As seen, point 367 of motor ring 366 may include an enlarged portion that increases in thickness as the point extends farther in the radial direction from a center of the rotor (e.g., negative X direction as seen in FIG. 3). This enlargement may expand the distance with which the point 367 of the motor ring may be able to interact and engage with the magnetic field as created by radial movement component 326. This enlarged portion may permit an extended distance of axial play (e.g., an increased vertical movement capable for the rotor and substrate support). Such a feature will be further discussed below. In embodiments, the full vertical motion range of the rotor (and thus substrate support and supported substrate) is achieved via maglev. Accordingly, in some embodiments no mechanical lifting apparatus is used to change a distance between a supported substrate and a thermal source disposed above the substrate.

Rotor 360 may further include encoder ring 364. As seen in FIG. 3, the encoder ring may include radially protruding or distinct, portions or points (e.g., point 365). As seen in the limited and exemplary view of FIG. 3, radially protruding may mean in the negative X direction.

In embodiments, the one or more distinct portions or points of the encoder ring and/or motor ring may contribute to an overall gear structure, or a ring including one or more gears. Thus, in embodiments, the encoder ring and/or motor ring may be a ring including a plurality of gears.

As seen within FIG. 4, in embodiments, the axial lift component 422 may include one or more motors (e.g., motors 436A-B) for generating a magnetic field. As previously discussed with respect to the previous figures, such motors within axial lift component may generate the magnetic field, which may interact or engage with a portion of the rotor, to provide a levitation force. In embodiments, such a force may raise the rotor (and any supported substrate) by a distance of D1 from the well bottom 450 (e.g., from a resting position). In embodiments, the stator and device may levitate the actuator ring and rotor (and thus the substrate support and supported substrate) anywhere from 0 mm to 6 mm (e.g., D1 may be anywhere from 0 mm to 6 mm) in some embodiments. In other embodiments the actuator ring and rotor (and thus the substrate support and supported substrate) have a vertical motion range of up to 4 mm, 5 mm, 6 mm, 7 mm, 8 mm, 9 mm, 10 mm, and so on.

In embodiments, the actuation ring 462 (and/or motor ring 466) may be made from a material that exhibits high magnetic permeability or is magnetizable (e.g., such as iron or another ferrous material), allowing it to interact effectively with the magnetic field. The actuation ring 462 may be configured in such a way that it surrounds the rotor but does not make physical contact with the stator 420, thus allowing for levitation. When a magnetic field is generated by the stator 420, the magnetic field lines may penetrate the housing walls and actuation ring 462, creating an upward magnetic force that counters the gravitational force acting on the rotor 460.

With references to FIGS. 3-4, in some embodiments, the housing or base of the substrate support device may serve to delineate an interior of the processing chamber from an exterior of the processing chamber. For instance, in some embodiments, the rotor and substrate support portion of the rotor may lie within the processing chamber, while the stator and stator components may lie outside of the processing chamber. For example, in embodiments, actuating components and sensors associated with the stator (e.g., radial movement component 326, centering component 330, radial sensor 332, axial sensor 338, axial lift component, etc.) may be disposed on an exterior surface of a processing chamber. Similarly, in embodiments, reactive regions associated with the rotor (e.g., motor ring 366, encoder ring 364, and/or actuation ring 362, etc.) may be disposed within a corresponding interior volume of the processing chamber.

In embodiments, the axial lift component(s) and/or radial movement component(s) of the mechanism may be or include any components capable of generating a magnetic field. In some cases, these components may be motors. In some cases these may be switched reluctance motors (SR motors, or SRMs). In some cases these may be any other type of motor capable of generating a magnetic field e.g., permanent magnet synchronous motors (PMSM), (brushless) DC motors (BLDC), induction motors, (reluctance) synchronous motors, etc.). Such an interaction may enable the stator to generate one or more magnetic fields, and the rotor to levitate and/or rotate with minimal friction.

In embodiments, the axial sensor(s) (e.g., sensors 338) may be or include any components capable of measuring the distance the rotor is lifted. Thus, in some cases, such component(s) may be or include a hall effect sensor. In other cases, the component may be or include an optical sensor (e.g., laser sensor, IR sensor, etc.), an ultrasonic sensor, a camera or image sensor, a capacitive senor, etc. In embodiments, sensor 338 may be embedded in, or extend through, the well bottom 350. In some embodiments, the sensor may rest on the exterior wall of the well bottom (and not pass into or through the exterior wall).

In embodiments, the radial movement components (e.g., component 326) and centering components (e.g., component 330) may include a working band, based on a specific permitted axial play (e.g., axial play 327 for component 326; axial play 331 for component 330) of an actuating component. In embodiments, the axial play may be a distance in the vertical direction that may be used to define the working band, or vertical distance, of effectiveness for a respective actuating component. Such a working band, derived from the permitted axial play, can be used to define a vertical distance with which a reactive region or component should be maintained if it is to be affected by the corresponding actuating component. In the case where a reactive component of the rotor axially moves so as to exceed or fail to reach the working band of the component (e.g., either through weak or over-delivered levitation), there may be a decrease, or loss, of effectiveness for that component. Otherwise stated, the reactive component should lie vertically within the corresponding distance of axial play and the working band of the respective actuating component if it is to be affected by the generated magnetic field. Thus, in embodiments, this axial play of an actuating component may serve to characterize the amount of axial movement, or variations in rotor height, that system may still be able to function with.

In a specific example focused on centering component 330, axial play 331 may be used to define a working band for the component 330. In embodiments, should the actuator ring 362 rise or fall so as to be outside the permitted axial play 331, or working band, of component 330, that portion of the system may fail, become unstable, or otherwise be rendered ineffective. Similarly, with respect to axial play 327, when the rotor is made to levitate, the radial movement component 326 and motor ring 366 may function, or more effectively function, when the motor ring may vertically align, or fall, within the working band of the radial movement component 326.

A separate way to frame the concept of axial play, is that axial play may indicate the region, distance, or space wherein the magnetic field or force generated by the corresponding actuating component of the stator may impart an effective force on the corresponding reactive region of the rotor.

Thus, having an enlarged axial play for each actuating component may be beneficial and introduce a more robust and precise system, given the enhanced capabilities for vertical motion provided by robust axial play values and robust working zone. Enlarging a thickness of protruding region or point (e.g., such as point 367) facing the direction of the corresponding actuating component may also aid in enlarging the possible axial movement of the rotor, since the possible axial movements can be greater, and the enlarged protruding regions or points may still lie within the working band, or distance, of axial play associated with an actuating component. Thus, enlarged protruding portions or points of the rotor reactive regions (as seen by point 367) may also enhance the capabilities of the system by allowing the rotor additional axial movement. Thus, by increasing the space, volume, and/or strength of a reactive region, the opportunities to interact with the generated magnetic field may be increased without changing the parameters or types of actuating components.

In embodiments, having a larger working band may allow for additional versatility in the vertical movement of the rotor. For example, the rotor may be capable of being raised and lowered to a larger variation of distances (e.g., D1) and still retain rotational and centering capabilities. Such additional versatility will have immediate impacts on any supported substrates, and the distance from such a substrate(s) to a heat source within the chamber which the device 300 is in. Added controllability in such a case may be advantageous as it may allow for added precision and controllability with respect to the heating process, and the heat delivered to the substrate. Additionally, in embodiments the increased vertical range of motion of the substrate support via magnetic levitation enables the omission of mechanical lifting mechanisms for mechanically lifting the substrate support device.

In embodiments, such an axial play 327 and working band of component 326 may span a vertical distance of 2 to 10 mm vertically, and still rest adjacently to the radial movement components. In embodiments, such a working band may rest adjacently to the radial movement components within the housing (while the radial movement component is exterior to the housing). In embodiments, such an axial play 331 and working band of component 330 may span a vertical distance of 2 to 10 mm. In embodiments, such a band may rest adjacently to the centering components within the housing (while the centering component is exterior to the housing).

In embodiments, any of the radially protruding portions or points (e.g., points 367, 365 and or portion of ring 362) may be or include discrete (or continuous in some cases) radially extending working or actuating points. For instance, in embodiments motor ring 366 includes 24 discrete, radially extending portions or points identical to point 367. Such additional points may be evenly spaced at the same height around an outer circumference of the motor ring.

In embodiments, any of the discrete points (or continuous region) of the actuator ring, encoder ring, and/or motor ring may radially protrude between 2 and 3 inches from an inner diameter of the rotor. In embodiments, any of the discrete points of the actuator ring, encoder ring, and/or motor ring may include any number of radially extending points or portions. In embodiments of a “continuous” ring or structure, spaces between discrete working points or actuating portions of motor ring 466B may be filled with ineffective material (e.g., a non-ferrous material), such that a ring may be continuous in visage but not in response to magnetic fields. For instance, in embodiments motor ring 366 may be a continuous ring. For example, the spaces between distinct points 367 as described above may be filled with a different material that is non-reactive to a magnetic field. In embodiments, any of the actuating ring, encoder ring, and/or motor ring may include any number of discrete points, or a continuous ring made of varying materials. In embodiments, any of the actuating ring, encoder ring, and/or motor ring may be a continuous ring made of uniform, or non-varying materials.

In embodiments, the housing 340 may include an outer wall 348, an inner wall 342, and a well 346 and well bottom 350 formed between the two walls. As previously mentioned, in embodiments, a portion of the rotor 360 may reside within the well 346.

In embodiments, the inner and outer walls may be anywhere between 1 and 3 millimeters (inclusively), in the X dimension (e.g., in thickness). In embodiments, the inner and outer walls may be larger than 3 millimeters in the X dimension.

In embodiments, an air gap may exist between the actuator ring and the bottom and side walls of the well. In embodiments, the air gap between the actuator ring and any of the bottom and/or side walls of the well may be between 0.5 mm to 1.0 mm.

FIG. 4 illustrates a cut-away view of a portion of an example substrate support device of FIG. 1, according to some embodiments of the present disclosure. FIGS. 3 and 4 may show cross-sectional side views of different regions a same substrate support device in embodiments.

Components and features as seen and described with respect to FIG. 3 may correspond, or be similar, to similar components as seen and described with respect to FIGS. 1-2B, and in particular with respect to FIG. 3. Thus, embodiments discussed with respect to FIG. 4 may incorporate and augment at least the embodiments described with respect to FIGS. 1-3. As seen in FIG. 4, in embodiments, a substrate support device 400 may include a stator 420, a housing 440, and a rotor 460 (which may be part of a substrate support). Such components may correspond to the stator, base, and rotor (and substrate support) as seen with respect to FIGS. 1-3. Such components may incorporate and augment at least the embodiments described therein.

As previously discussed, stator 420 may include actuating portions and sensing portions. Stator 420 may include axial lift components (e.g., component 422), radial movement components (e.g., component 426), and centering components (not shown with respect to FIG. 4). Stator 420 may further include axial sensors (e.g., sensor 438) and rotational sensors (e.g., sensor 432).

Stator may generate various forces and magnetic fields for interacting with the rotor 460. As previously discussed, rotor 460 may rest within the well 446 of the housing 440 (e.g., between an outer wall 448 and an inner wall 442). Rotor 460 may be circular in shape, and include reactive regions, such as actuator ring 462 and motor ring 466. As seen in FIG. 4, the motor ring may include radially protruding or distinct, portions or points (e.g., point 467 such as a tooth or gear). As seen, point 467 of motor ring 466 may include an enlarged portion that increases in thickness as the point extends farther in the radial direction from the center of the rotor (e.g., negative X direction as seen in FIG. 4). As discussed with respect to FIG. 3, this enlargement may expand the distance with which the point 467 of the motor ring may be able to interact and engage with the magnetic field as created by radial movement component 426. This enlarged portion may permit an extended distance of axial play (e.g., an increased vertical movement capable for the rotor and substrate support). Such a feature will be further discussed below. In embodiments, the full vertical motion range of the rotor (and thus substrate support and supported substrate) is achieved via maglev. Accordingly, in some embodiments no mechanical lifting apparatus is used to change a distance between a supported substrate and a thermal source disposed above the substrate.

Rotor 460 may further include encoder ring 464. As was similarly discussed with respect to FIG. 3, the encoder ring may include radially protruding or distinct, portions or points (e.g., point 465). As seen in the limited and exemplary view of FIG. 4, radially protruding may mean in the negative X direction.

In embodiments, the one or more distinct portions or points of the encoder ring and/or motor ring may contribute to an overall gear structure, or a ring including one or more gears. Thus, in embodiments, the encoder ring and/or motor ring may be a ring including a plurality of gears.

As seen within FIG. 4, in embodiments, the axial lift component 422 may include one or more motors (e.g., motors 436A-B) for generating a magnetic field. Such motors within axial lift component 422 may generate the magnetic field, which may interact or engage with a portion of the rotor, to provide a levitation force. In embodiments, such a force may raise the rotor (and any supported substrate) by a distance of D1 from the well bottom 450 (e.g., from a resting position). In embodiments, the stator and device may levitate the actuator ring and rotor (and thus the substrate support and supported substrate) anywhere from 0 mm to 6 mm (e.g., D1 may be anywhere from 0 mm to 6 mm) in some embodiments. In other embodiments the actuator ring and rotor (and thus the substrate support and supported substrate) have a vertical motion range of up to 4 mm, 5 mm, 6 mm, 7 mm, 8 mm, 9 mm, 10 mm, and so on.

In embodiments, the actuation ring 462 (and/or motor ring 466) may be made from a material that exhibits high magnetic permeability or is magnetizable (e.g., such as iron or another ferrous material), allowing it to interact effectively with the magnetic field. The actuation ring 462 may be configured in such that it surrounds the rotor but does not make physical contact with the stator 420, thus allowing for levitation. When field 439 is generated by the stator 420, the magnetic field lines may penetrate the housing walls and actuation ring 462, creating an upward magnetic force that counters the gravitational force acting on the rotor 460.

As discussed with respect to FIG. 3, in embodiments, the axial lift component(s) and/or radial movement component(s) of the mechanism may be or include any components capable of generating a magnetic field. In some cases, these components may be motors. In some cases these may be switched reluctance motors (SR motors, or SRMs). In some cases these may be any other type of motor capable of generating a magnetic field e.g., permanent magnet synchronous motors (PMSM), (brushless) DC motors (BLDC), induction motors, (reluctance) synchronous motors, etc.). Such an interaction may enable the stator to generate one or more magnetic fields, and the rotor to levitate and/or rotate with minimal friction.

In embodiments, the axial sensor(s) (e.g., sensors 438) may be or include any components capable of measuring the distance the rotor is lifted. Thus, in some cases, such component(s) may be or include a hall effect sensor. In other cases, the component may be or include an optical sensor (e.g., laser sensor, IR sensor, etc.), an ultrasonic sensor, a camera or image sensor, a capacitive senor, etc. In embodiments, sensor 438 may be embedded in, or extend through the well bottom 450. In some embodiments, the sensor may rest on the exterior wall of the well bottom (and not pass into or through the exterior wall).

As discussed with respect to FIG. 3, in embodiments, the radial movement components (e.g., component 426) and centering components (seen in FIG. 3; not shown with respect to FIG. 4) may include a working band, based on a specific permitted axial play (e.g., axial play 427 for component 426; axial play 431 for the centering component) of an actuating component. In embodiments, the axial play may be distance in the vertical direction that may be used to define the working band, or vertical distance of effectiveness for a respective actuating component. Such a working band, derived from the permitted axial play, can be used to define a vertical distance with which a reactive region or component should be maintained if it is to be affected by the corresponding actuating component. In the case where a reactive component of the rotor axially moves so as to exceed or fail to reach the working band of the component (e.g., either through weak or over-delivered levitation), there may be a decrease or loss of effectiveness for that component. Otherwise stated, the reactive component should lie vertically within the corresponding distance of axial play and the working band of the respective actuating component if it is to be affected by the generated magnetic field. Thus, in embodiments, this axial play may serve to characterize the amount of axial movement, or variations in rotor height, that system may still be able to function with.

In a specific example focused on centering component (not shown with respect to FIG. 4), axial play 431 may be used to define a working band for the component. In embodiments, should the actuator ring 462 rise or fall so as to be outside the permitted axial play, or working band, of the component, that portion of the system may fail, become unstable, or otherwise be rendered ineffective. Similarly, with respect to axial play 427, when the rotor is made to levitate, the radial movement component 426 and motor ring 466 may function, or more effectively function, when the motor ring may vertically align, or fall, within the working band of the radial movement component 426.

A separate way to frame the concept of axial play, is that axial play may indicate the region, distance, or space, wherein the magnetic field or force generated by the corresponding actuating component of the stator may impart an effective force on the corresponding reactive region of the rotor.

As previously discussed, having an enlarged axial play for each actuating component may be beneficial and introduce a more robust and precise system, given the enhanced capabilities for vertical motion provided by robust axial play values and robust working zone. Enlarging a thickness of protruding region or point (e.g., such as point 467) facing the direction of the corresponding actuating component may also aid in enlarging the possible axial movement of the rotor, since the possible axial movements can be greater, and the enlarged protruding regions or points may still lie within the working band, or distance of axial play associated with an actuating component. Thus, enlarged protruding portions or points of the rotor reactive regions (as seen by point 467) may also enhance the capabilities of the system by allowing the rotor additional axial movement. Thus, by increasing the space, volume, and/or strength of a reactive region, the opportunities to interact with the generated magnetic field may be increased without changing the parameters or types of actuating components.

In embodiments, having a larger working band, may allow for additional versatility in the vertical movement of the rotor. For example, the rotor may be capable of being raised and lowered to a larger variation of distances (e.g., D1) and still retain rotational and centering capabilities. Such additional versatility will have immediate impacts on any supported substrates, and the distance from such a substrate(s) to a heat source within the chamber which the device 400 is in. Added controllability in such a case may be advantageous as it may allow for added precision and controllability with respect to the heating process, and the heat delivered to the substrate. Additionally, in embodiments the increased vertical range of motion of the substrate support via magnetic levitation enables the omission of mechanical lifting mechanisms for mechanically lifting the substrate support device.

In embodiments, such an axial play 427 and working band of component 426 may span a vertical distance of 2 to 10 mm vertically, and still rest adjacently to the radial movement components. In embodiments, such a working band may rest adjacently to the radial movement components within the housing (while the radial movement component is exterior to the housing). In embodiments, such an axial play 431 and working band of the centering component may span a vertical distance of 2 to 10 mm. In embodiments, such a band may rest adjacently to the centering components within the housing (while the centering component is exterior to the housing).

In embodiments, any of the radially protruding portions or points (e.g., points 467, 465 and or portion of ring 462) may be or include discrete (or continuous in some cases), radially extending working, or actuating, points. For instance, in embodiments, motor ring 466 includes 24 discrete, radially extending portions or points identical to point 467. Such additional points may be evenly spaced at the same height around an outer circumference of the motor ring.

In embodiments, any of the discrete points (or continuous region) of the actuator ring, encoder ring, and/or motor ring may radially protrude between 2 and 3 inches from an inner diameter of the rotor. In embodiments, any of the discrete points of the actuator ring, encoder ring, and/or motor ring may include any number of radially extending points or portions. In embodiments of a “continuous” ring or structure, spaces between discrete working points or actuating portions of motor ring 466B may be filled with ineffective material, such that a ring may be continuous in visage but not in response to magnetic fields. For instance, in embodiments, motor ring 466 may be a continuous ring. For example, the spaces between distinct points 467 as described above may be filled with different material that is non-reactive to a magnetic field. In embodiments, any of the actuating ring, encoder ring, and/or motor ring may be any number of discrete points, or a continuous ring made of varying materials. In embodiments, any of the actuating ring, encoder ring, and/or motor ring may include a continuous ring made of uniform, or non-varying materials.

In embodiments, the housing 440 may include an outer wall 448, an inner wall 442, and a well 446 and well bottom 450 formed between the two walls. As previously mentioned, in embodiments, a portion of the rotor 460 may reside within the well 446.

In embodiments, the inner and outer walls may be anywhere between 1 and 3 millimeters (inclusively), in the X dimension (e.g., in thickness). In embodiments, the inner and outer walls may be larger than 3 millimeters, in the X dimension.

In embodiments, an air gap may exist between the actuator ring, and the bottom, and side walls of the well. In embodiments, the air gap between the actuator ring, and any of the bottom, and/or side walls of the well may be between 0.5 mm to 1.0 mm.

As will be further discussed with respect to FIGS. 5A-6B, the axial lift component may generate a magnetic field to interact and lift the rotor through the actuator ring of the rotor. The radial movement component may generate a magnetic field to interact and rotate the rotor through the motor ring of the rotor. All such movement may be orchestrated and controlled via a controller (as was seen and described with respect to FIG. 1).

In embodiments as will be further discussed with respect to FIGS. 5A-6B, the axial sensor 438 may interact with the actuator ring 462 to generate data reflective of the distance D1 or axial position of the actuator ring and rotor. Similarly, the radial sensor 432 may interact with the encoder ring 464 and/or points 465 to generate data reflective of the movement, speed, or rotational position of the encoder ring and rotor. All such data and measurements may be received via a controller of the system and device (as described with respect to FIGS. 1) and thus form a feedback, or closed loop. The controller may effect any adjustments or updates to the lift and rotation of the rotor based on such feedback from the radial sensor or axial sensor.

FIGS. 5A-B illustrate views and embodiments of an example axial levitation mechanism of the example substrate support device of FIG. 2, according to some embodiments of the present disclosure.

Components of FIGS. 5A-B may correspond, or be similar, to similar components as seen and described in FIGS. 2-4C. Accordingly, the components and embodiments discussed with respect to FIGS. 5A-B may incorporate and augment similar components and embodiments discussed with respect to FIG. 2.

Although FIGS. 5A-B illustrate a cross-sectional view of components (e.g., sensors, motors, etc.) of the stator, housing and rotor, many and any number of such components and instances of the configurations as seen in FIGS. 5A-B may be included along a circumference of the stator, housing, and rotor, and the substrate support device at large.

FIG. 5A illustrates a cut-away view of an example axial levitation mechanism of the example substrate support device of FIG. 1, according to some embodiments of the present disclosure.

Components and features as seen and described with respect to FIG. 5A may correspond, or be similar, to similar components as seen and described with respect to FIGS. 1-3. Thus, embodiments discussed with respect to FIG. 5A may incorporate and augment at least the embodiments described with respect to FIGS. 3.

In embodiments, rotor 560A may rest within a well 546A formed by housing 540A. In embodiments, while the system is not actively engaged (e.g., motors 530A and 532A of axial lift component 522A are off), no levitation may be occurring, and the rotor, and actuation ring 562A may be at a lowest vertical position. In embodiments, the actuation ring 562A may physically contact a bottom surface of the well 546A.

FIG. 5B illustrates a cut-away view of an example axial levitation mechanism of the example substrate support device of FIG. 1B, according to some embodiments of the present disclosure.

Components and features as seen and described with respect to FIG. 5B may correspond, or be similar, to similar components as seen and described with respect to FIGS. 1-5A. Thus, embodiments discussed with respect to FIG. 5B may incorporate and augment at least the embodiments described with respect to FIGS. 1-5A.

In embodiments, rotor 560B may rest within a well 546B formed by housing 540. As previously mentioned, while the system is not actively engaged, no levitation may be occurring, and the rotor, and actuation ring 562B may be at a lowest vertical position or at a resting position. In embodiments, the actuation ring 562B may physically contact a bottom surface of the well 546B.

In embodiments, when motors 530B and 532B may be engaged (as seen in FIG. 5B), such motors of axial lift component 522B may provide a magnetic field 534B. In embodiments, once motors 530B and 532B have been engaged, the field may induce actuator ring 562B to vertically align with the flux field. In such a way, the axial lift component 522B may levitate the actuation ring 562B and rotor 560B (as well as the substrate support surface and any supported substrate).

In embodiments, motors 530B and 532B may provide a magnetic force to magnetically levitate the rotor, as will be shown with respect to FIG. 5B. In embodiments, motors 530B and 532B may be switched reluctance motors (SR motors or SRMs), particularly one designed for the purpose of magnetic levitation. In embodiments, the SR motors 530B and 532B may be embedded within the stator 520B. In embodiments, the levitation may be achieved through the interaction between field motors 530B and 532B and an actuation ring 562B to raise the rotor 560B.

In embodiments, the stator and SR motor component may be equipped with a series of electromagnets. These electromagnets may be positioned to create a controlled magnetic field. For instance, when an electric current is passed through such electromagnets field 534B may be generated. Through control of the electric current, the intensity and spatial orientation generated by the motors may be modulated and controlled. A control system (as was described with respect to FIGS. 1-2) may be used to manage current flow, thus modulating, or altering the characteristics of field 534B.

In embodiments, the actuation ring 562B may be made from a material that exhibits high magnetic permeability or is magnetizable, allowing it to interact effectively with the magnetic field. The actuation ring 562B may be configured in such that it surrounds the rotor but does not make physical contact with the stator 520B, thus allowing for levitation. When field 534B is generated by the stator 520B, the magnetic field lines may penetrate the actuation ring 562B, creating an upward magnetic force that counters the gravitational force acting on the rotor 560B.

In embodiments, an axial sensor 524B may be used to measure and make adjustments to the levitation height D1, and make adjustment to the motors. Axial sensor(s) 524B (which may be integrated into the system) may provide real-time feedback on the levitating position of the rotor. Such feedback may then be used to adjust the current in the electromagnets of the SR motor 530B and 532B, thus continuously controlling field 534B. By fine-tuning the magnetic field in response to the rotor's motion, the system may maintain a constant levitation height and stabilize the rotor during operation.

In embodiments, axial sensor(s) 524B may be or include any axial sensor (i.e., sensor) capable of sensing movement and/or position of the actuator ring. E.g., axial sensor 524 may be a hall effect sensor.

In embodiments, the system may levitate the actuator ring and rotor a distance of D1. In embodiments, the system may levitate the actuator ring and rotor anywhere from 0 mm to 6 mm.

In embodiments, an air gap may exist between the actuator ring, and the bottom, and side walls of the well. In embodiments, the air gap between the actuator ring, and any of the bottom, and/or side walls of the well may be between 0.5 mm to 1.0 mm.

FIGS. 6A-B illustrate a partial top-down view of an example substrate support device of FIG. 2, according to some embodiments of the present disclosure.

Components of FIGS. 6A-B may correspond, or be similar, to similar components as seen and described in FIGS. 2-5B. Accordingly, the components and embodiments discussed with respect to FIGS. 6A-B may incorporate and augment similar components and embodiments discussed with respect to FIG. 2-5B.

FIG. 6A illustrates a partial view of an example radial positioning mechanism of the example substrate support device of FIG. 2, according to some embodiments of the present disclosure.

Components and features as seen and described with respect to FIG. 6A may correspond, or be similar, to similar components as seen and described with respect to FIGS. 1-5B. Thus, embodiments discussed with respect to FIG. 6A may incorporate and augment at least the embodiments described with respect to FIGS. 1-5B.

As seen, FIG. 6A illustrates an exemplary top-down view of an upper left-hand portion of a substrate support device 600A including a rotor 660, stator 620, and housing 640. The view seen in FIG. 6A may be thought of as a top-down view corresponding from about the 9:00 position of an analog clock, to a 12:00 position of an analog clock. In a similar manner as was seen with respect to FIG. 2B, the view seen in FIG. 6A is highly simplified, and an embodiment of the components shown for the sake of demonstration.

As seen in FIG. 6A, a rotor 660 may include a motor ring 666 including distinct points 667A-B, as has been previously described and seen with respect to FIGS. 1-5B (and incorporating and augmenting those embodiments described therein). Motor ring 666 and rotor 660 may be seen within a well 646A of a housing 640 including an outer wall 648 and an inner wall 642. In embodiments, radial movement components 626A-B of the stator 620 may be positioned on the outer portion of the stator 620.

As was seen and described with respect to the motors of FIG. 5B, the radial movement components 626A-B may similarly generate a magnetic field, and exert an attractive (or repulsive) force on points 667A-B of the motor ring of the rotor 660. When the rotor is levitated (as was described with respect to FIG. 5B), the stator may thus induce the rotor to rotate. E.g., in a simplified embodiments where the rotor is being made to rotate clockwise, the radial movement component 626A may first be switched to generate a field, and exert an attractive force on point 667A. Once the rotor has rotated such that point 667A has aligned with radial movement component 626A, the component may be switched such that no field is generated, and no rotational force is exerted. In tandem, the radial movement component 626B may be switched to generate a field, and exert an attractive force on point 6667A. The rotor may then be induced to rotate such that point 667A has aligned with radial movement component 656B. The above description is exemplary. Such a pattern and process may continue, for many radial movement components and corresponding distinct points within the motor ring and rotor. In such a way, the electrical power through components of the stator may be controlled to generate a magnetic flux field, which may in sequence be used to rotate the rotor 660 of FIG. 6A.

While one strategy for rotating the rotor using the components of FIG. 6A have been described. Note that the example is non-limiting, and that any such control strategy may be applied to the components, as feasible.

FIG. 6B illustrates a partial view of an example radial positioning sensing mechanism of the substrate support device of FIG. 2, according to some embodiments of the present disclosure.

Components and features as seen and described with respect to FIG. 6B may correspond, or be similar, to similar components as seen and described with respect to FIGS. 1-6A. Thus, embodiments discussed with respect to FIG. 6B may incorporate and augment at least the embodiments described with respect to FIGS. 1-6A.

As seen, FIG. 6B illustrates an exemplary top-down view of an upper left-hand portion of a substrate support device 600B including a rotor 660, stator 620, and housing 640. The view seen in FIG. 6B may be thought of as a top-down view corresponding from about the 9:00 position of an analog clock, to a 12:00 position of an analog clock. The view seen in FIG. 6B is highly simplified, and an embodiment of the components shown for the sake of demonstration.

As seen in FIG. 6B, a rotor 660 include an encoder ring 664 with distinct points 665A-B. Rotor 660 and the encoder ring may be seen within a well 646 of a housing 640 including an outer wall 648 and an inner wall 642. In embodiments, rotational sensors 630A-B of the stator may be positioned on the outer portion of the outer wall.

As was seen and described with respect to the axial sensor(s) of FIG. 5B, the rotational sensors 630A-B may similarly sense the passage of a point (e.g., point 665A-B) of the encoder ring. When the rotor is rotated, thus, the encoder ring, in combination with the rotational sensors, may be used to generate data indicative of the speed and/or rotational position of the rotor with respect to the stator. Thus, a feedback loop can be created and the rotational data such as movement, position, and speed of the rotor as it rotates may be measured. Such data may be processed by a controller to more accurately know the real-time position of the rotor, and make adjustments.

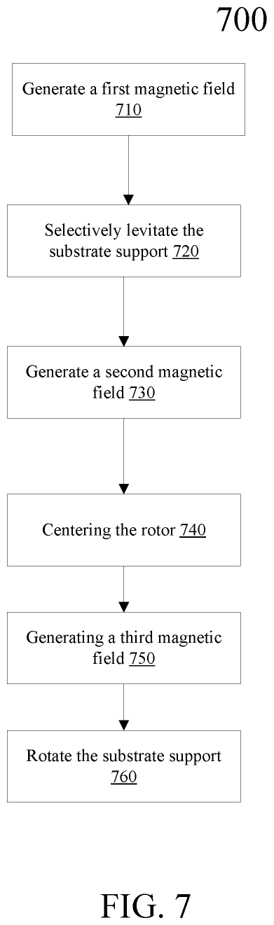

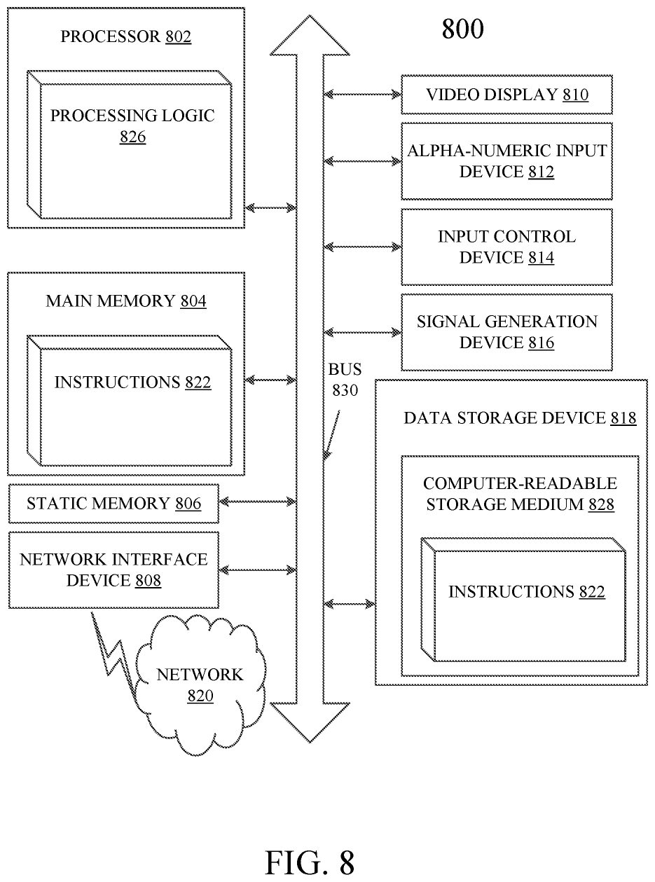

FIG. 7 is a flow diagram of an example method of operating the substrate support device of FIG. 1, in accordance with one embodiment of the present disclosure.

Method 700 may be performed by processing logic that can include hardware (circuitry, dedicated logic, etc.), software (e.g., instructions run on a processing device), or a combination thereof. In one implementation, some, or all of the operations of method 700 can be performed by one or more components of system 100 of FIG. 1.

At block 710, processing logic can generate a first magnetic field. In some embodiments, processing logic can generate a first magnetic field via a stator of a base of a substrate support device to cause a first magnetic interaction with a first ferrous ring of a rotor attached to a substrate support of the substrate support device, wherein the first magnetic interaction controls a vertical position of the substrate support.

At block 720, processing logic can selectively levitate the substrate support. In some embodiments, processing logic can selectively levitate the substrate support to any vertical distance within a range from 0 mm to 6 mm above a resting position using the first magnetic field.

At block 730, processing logic can generate a second magnetic field. In some embodiments, processing logic can generate a second magnetic field via the stator to cause a second magnetic interaction with the first ferrous ring of the rotor, wherein the second magnetic interaction centers the substrate support to the base.

At block 740, processing logic may center the rotor. In some embodiments, processing logic can center the substrate support with respect to the base via the second magnetic interaction over the vertical range.

At block 750, processing logic may generate a third magnetic field. In some embodiments, processing logic can generate a third magnetic field via the stator to cause a third magnetic interaction with a second ferrous ring of the rotor attached to the substrate support, wherein the third magnetic interaction rotates the substrate support.

At block 760, processing logic may rotate the substrate support. In some embodiments, processing logic can rotate the support device via the third magnetic an interaction over the vertical distance.

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplarily language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

A digital computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a digital computing environment. The essential elements of a digital computer a central processing unit for performing or executing instructions and one or more memory devices for storing instructions and digital data. The central processing unit and the memory can be supplemented by, or incorporated in, special purpose logic circuitry or quantum simulators. Generally, a digital computer will also include, or be operatively coupled to receive digital data from or transfer digital data to, or both, one or more mass storage devices for storing digital data, e.g., magnetic, magneto-optical disks, optical disks, or systems suitable for storing information. However, a digital computer need not have such devices.

Digital computer-readable media suitable for storing digital computer program instructions and digital data include all forms of non-volatile digital memory, media and memory devices, including by way of example semiconductor memory devices, e.g., EPROM, EEPROM, and flash memory devices; magnetic disks, e.g., internal hard disks or removable disks; magneto-optical disks; CD-ROM and DVD-ROM disks.

Control of the various systems described in this specification, or portions of them, can be implemented in a digital computer program product that includes instructions that are stored on one or more non-transitory machine-readable storage media, and that are executable on one or more digital processing devices. The systems described in this specification, or portions of them, can each be implemented as an apparatus, method, or system that may include one or more digital processing devices and memory to store executable instructions to perform the operations described in this specification.

While this specification contains many specific embodiment details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily rely on the particular order shown, or sequential order, to achieve desirable results. In some cases, multitasking and parallel processing may be advantageous.

What is claimed is:

1. A substrate support device comprising:
a base secured to a processing chamber, the base comprising a stator configured to generate a first magnetic field, a second magnetic field, and a third magnetic field; and
a substrate support positioned above the base and configured to support a substrate, the substrate support comprising a rotor that comprises:
a first reactive region configured to interact with the first magnetic field to magnetically control a vertical position of the substrate support, and to interact with the second magnetic field to magnetically center the substrate support to the base; and
a second reactive region configured to interact with the third magnetic field to magnetically rotate the substrate support;
wherein the first magnetic field and the first reactive region are configured to selectively levitate the substrate support to any distance within a range from 0 mm to 6 mm above a resting position.

2. The substrate support device of claim 1, wherein the first reactive region and the second reactive region of the rotor are configured to effectively interact with the second magnetic field and the third magnetic field of the stator, respectively, at any vertical position that ranges from 0 mm to 6 mm above the resting position of the substrate support.

3. The substrate support device of claim 1, wherein the stator comprises a first actuating component for generating the first magnetic field, a second actuating component for generating the second magnetic field, and a third actuating component for generating the third magnetic field, wherein at least one of the second actuating component or the third actuating component permit a distance of axial play that is between 2 mm and 10 mm.

4. The substrate support device of claim 3, wherein the third actuating component has a first height, and wherein the second reactive region has a second height that is greater than the first height.

5. The substrate support device of claim 3, wherein the second actuating component has a first height, and wherein the first reactive region has a second height that is less than the first height.

6. The substrate support device of claim 1, wherein the first reactive region comprises a first ferrous ring and the second reactive region comprises a second ferrous ring comprising a plurality of gears.

7. The substrate support device of claim 1, wherein the processing chamber is a rapid thermal processing (RTP) chamber configured to administer a thermal process to the substrate via a thermal energy source.

8. The substrate support device of claim 1, wherein the substrate support is disposed within a chamber, and wherein the stator comprises a magnetic rotational sensor disposed outside of the chamber configured to interact with an encoder ring of the stator through a wall of the chamber to generate data indicative of the rotational position of the rotor.

9. The substrate support device of claim 1, wherein the substrate support is disposed within a chamber, and wherein the stator comprises a magnetic axial sensor configured to interact with the first reactive region of the rotor through a wall of the chamber to generate data indicative of a vertical position of the rotor.

10. A system comprising:
a processing chamber;
a base disposed within the processing chamber and secured to a floor of the processing chamber, the base comprising a stator configured to generate a first magnetic field, a second magnetic field, and a third magnetic field; and
a substrate support positioned above the base and configured to support a substrate, the substrate support comprising a rotor that comprises:
a first reactive region configured to interact with the first magnetic field to magnetically control a vertical position of the substrate support and to interact with the second magnetic field to magnetically center the substrate support to the base; and
a second reactive region configured to interact with the third magnetic field to magnetically rotate the rotor;
wherein the first magnetic field and the first reactive region are used to selectively levitate the substrate support to any distance within a range from 0 mm to 6 mm above a resting position.

11. The system of claim 10, wherein the first reactive region and the second reactive region of the rotor are configured to effectively interact with the second magnetic field and the third magnetic field of the stator, respectively, at any vertical position that ranges from 0 mm to 6 mm above the resting position of the substrate support.

12. The system of claim 10, wherein the stator comprises a first actuating component for generating the first magnetic field, a second actuating component for generating the second magnetic field, and a third actuating component for generating the third magnetic field, wherein at least one of the second actuating component or the third actuating component permit a distance of axial play that is between 2 mm and 10 mm.

13. The system of claim 12, wherein the third actuating component has a first height, and wherein the second reactive region has a second height that is greater than the first height.

14. The system of claim 12, wherein the second actuating component has a first height, and wherein the first reactive region has a second height that is less than the first height.

15. The system of claim 10, wherein the first reactive region comprises a first ferrous ring and the second reactive region comprises a second ferrous ring comprising a plurality of gears.

16. The system of claim 10, wherein the processing chamber is a rapid thermal processing (RTP) chamber configured to administer a thermal process to the substrate via a thermal energy source.

17. The system of claim 10, wherein the substrate support is disposed within a chamber, and wherein the stator comprises a magnetic rotational sensor disposed outside of the chamber configured to interact with an encoder ring of the stator through a wall of the chamber to generate data indicative of the rotational position of the rotor.

18. The system of claim 10, wherein the substrate support is disposed within a chamber, and wherein the stator comprises a magnetic axial sensor configured to interact with the first reactive region of the rotor through a wall of the chamber to generate data indicative of a vertical position of the rotor.

19. A method comprising:
generating a first magnetic field via a stator of a base of a substrate support device to cause a first magnetic interaction with a first ferrous ring of a rotor attached to a substrate support of the substrate support device, wherein the first magnetic interaction controls a vertical position of the substrate support;
selectively levitating the substrate support to any vertical distance within a range from 0 mm to 6 mm above a resting position using the first magnetic field;
generating a second magnetic field via the stator to cause a second magnetic interaction with the first ferrous ring of the rotor, wherein the second magnetic interaction centers the substrate support to the base;
centering the substrate support with respect to the base via the second magnetic interaction over the vertical range;
generating a third magnetic field via the stator to cause a third magnetic interaction with a second ferrous ring of the rotor attached to the substrate support, wherein the third magnetic interaction rotates the substrate support; and
rotating the support device via the third magnetic interaction over the vertical distance.

20. The method of claim 19, wherein the first ferrous ring and the second ferrous ring of the rotor are configured to effectively interact with the second magnetic field and the third magnetic field of the stator, respectively, at any vertical position that ranges from 0 mm to 6 mm above the resting position of the substrate support.
